(19) United States
(12) Patent Application Publication
(10) Pub. No.: US 2026/0282289 A1
(43) Pub. Date: Sep. 17, 2026

(54) ELECTRONIC DEVICE AND COOLING ASSEMBLY

(71) Applicants: INVENTEC (PUDONG) TECHNOLOGY CORPORATION, Shanghai (CN); INVENTEC CORPORATION, Taipei City (TW)

(72) Inventors: Guoping WU, Shanghai (CN); Lian-Fei ZHANG, Shanghai (CN)

(73) Assignees: INVENTEC (PUDONG) TECHNOLOGY CORPORATION, Shanghai (CN); INVENTEC CORPORATION, Taipei City (TW)

(21) Appl. No.: 19/214,152

(22) Filed: May 21, 2025

(30) Foreign Application Priority Data
Mar. 12, 2025 (CN) 202510294519.3

(51) Int. Cl. H05K 7/20; G11B 33/14

(52) U.S. Cl. CPC H05K 7/20509; G11B 33/1413; H05K 7/20327; H05K 7/20336

(57) ABSTRACT

An electronic device includes a cooling assembly and at least one hard disk drive. The cooling assembly includes a vapor chamber and a plurality of thermally conductive structures. The plurality of thermally conductive structures are arranged side by side on two opposite sides of the vapor chamber to form at least one cooling space. The plurality of thermally conductive structures are thermally coupled to the vapor chamber. The at least one hard disk drive is located in the at least one cooling space, and is thermally coupled to one of the plurality of thermally conductive structures.

### CROSS-REFERENCE TO RELATED APPLICATIONS

This non-provisional application claims priority under 35 U.S.C. § 119(a) on Patent Application No(s). 202510294519.3 filed in C HINA , on M arch 12th, 2025, the entire contents of which are hereby incorporated by reference.

### BACKGROUND OF THE INVENTION

### Technical Field of the Invention

The invention relates to an electronic device and a cooling assembly, more particularly to an electronic device and a cooling assembly whose thermally conductive structures are arranged side by side on two opposite sides of a vapor chamber.

### Description of the Related Art

Nowadays, with the rapid development of technology, most of enterprises may deal with various business (e.g., storing data, files and information) via hard disk drives of a server for improving work efficiency.

In order to deal with the increasing amount of data, the quantity of the hard disk drives has increased. The hard disk drives may generate a lot of heat during operation. Generally, the hard disk drives can be cooled via a liquid cooling system. However, the cooling efficiency for hard disk drives is still insufficient, thereby adversely affecting the operation of the hard disk drives. Therefore, improving the cooling efficiency for the hard disk drives is one of the key issues that researchers need to address.

### SUMMARYOF THE INVENTION

The invention provides an electronic device and a cooling assembly in order to improve the cooling efficiency for the hard disk drives.

One embodiment of the invention provides an electronic device including a cooling assembly and at least one hard disk drive. The cooling assembly includes a vapor chamber and a plurality of thermally conductive structures. The plurality of thermally conductive structures are arranged side by side on two opposite sides of the vapor chamber to form at least one cooling space. The plurality of thermally conductive structures are thermally coupled to the vapor chamber. The at least one hard disk drive is located in the at least one cooling space, and is thermally coupled to one of the plurality of thermally conductive structures.

Another embodiment of the invention provides a cooling assembly configured for at least one hard disk drive to be disposed. The cooling assembly includes a vapor chamber and a plurality of thermally conductive structures. The plurality of thermally conductive structures are arranged side by side on two opposite sides of the vapor chamber to form at least one cooling space. The plurality of thermally conductive structures are thermally coupled to the vapor chamber. The at least one cooling space is configured for the at least one hard disk drive to be thermally coupled to one of the plurality of thermally conductive structures.

According to the electronic device and the cooling assembly disclosed in the above embodiment, the thermally conductive structures are arranged side by side on the two opposite sides of the vapor chamber to together form in shape of fishbone and form the at least one cooling space for the at least one hard disk drive to be disposed. Therefore, the heat generated by the at least one hard disk drive during operation can be transferred to the vapor chamber separately, thereby the heat transmission can be more evenly. Accordingly, the cooling efficiency for the at least one hard disk drive can be improved.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a perspective view of an electronic device and a chassis in accordance with an embodiment of the invention;

FIG. 2 is an exploded view of the electronic device in FIG. 1;

FIG. 3 is a perspective view of a cooling assembly of the electronic device in FIG. 1;

FIG. 4 is a perspective view of the cooling assembly of the electronic device in FIG. 1; and

FIG. 5 is an enlarged perspective view showing that a cooling fluid flows in the cooling assembly of the electronic device in FIG. 2.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

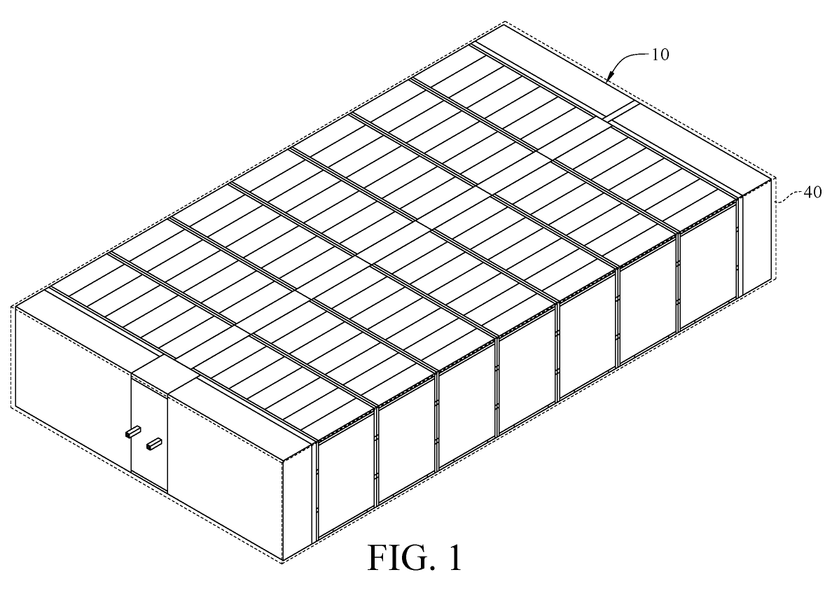

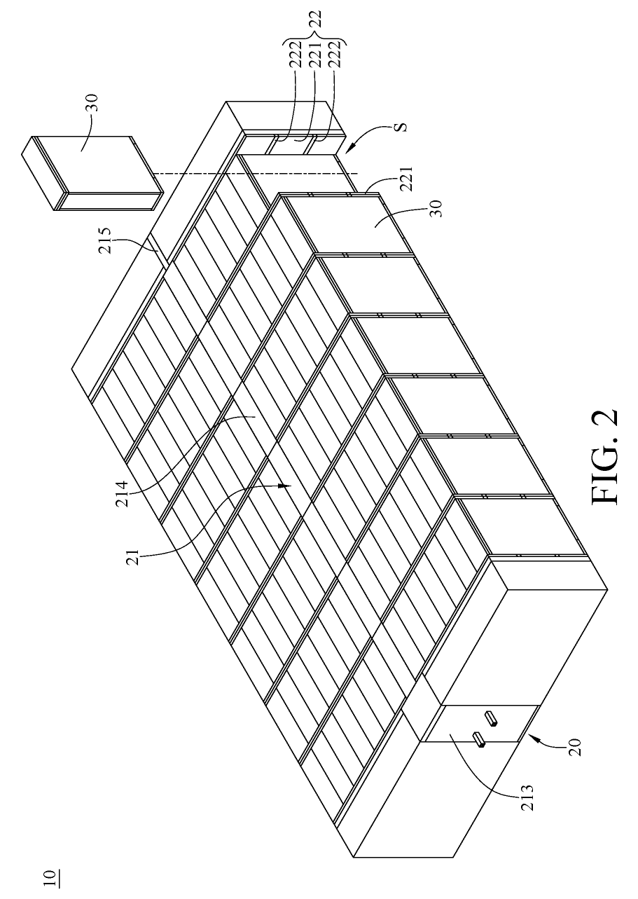

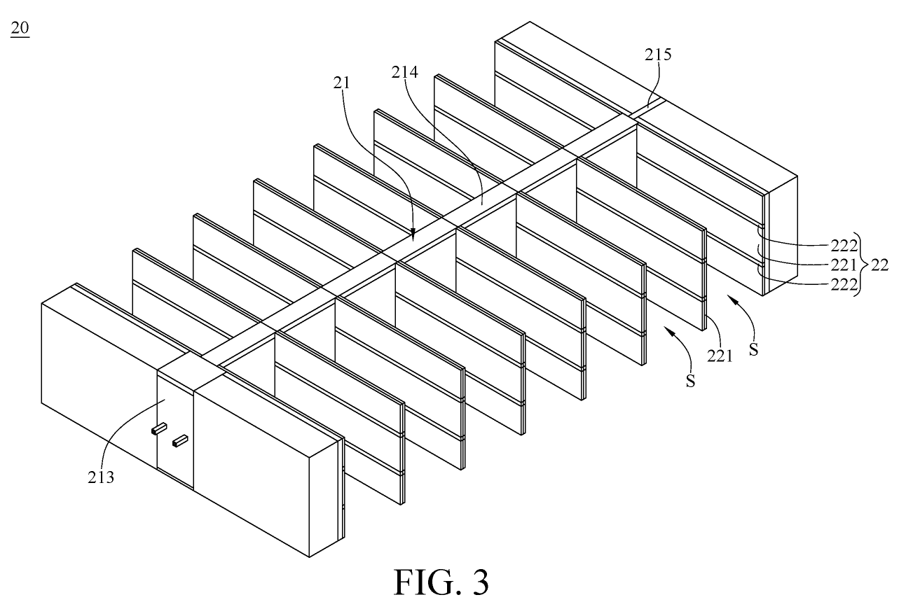

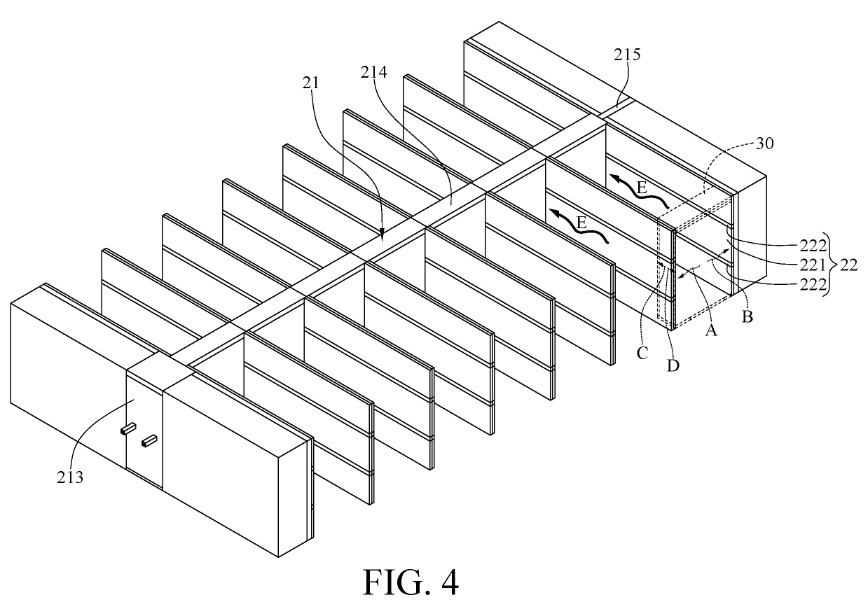

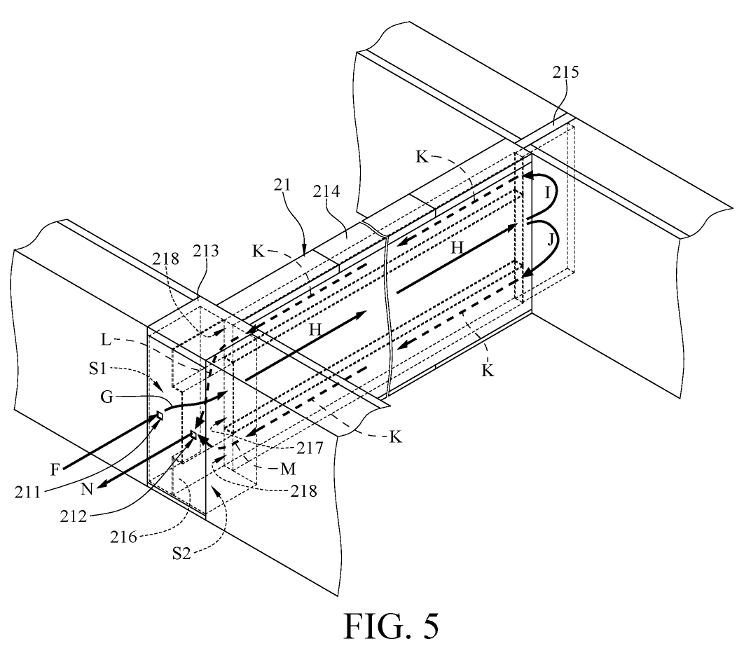

Please refer to FIG. 1 to FIG. 5, where FIG. 1 is a perspective view of an electronic device 10 and a chassis 40 in accordance with an embodiment of the invention, FIG. 2 is an exploded view of the electronic device 10 in FIG. 1, FIG. 3 is a perspective view of a cooling assembly of the electronic device 10 in FIG. 1, FIG. 4 is a perspective view of the cooling assembly of the electronic device 10 in FIG. 1, and FIG. 5 is an enlarged perspective view showing that a cooling fluid flows in the cooling assembly 20 of the electronic device 10 in FIG. 2.

In this embodiment, the electronic device 10 is in a form of, for example, JBOD (Just a Bunch Disks). The so-called “JBOD” refers to assembling multiple hard disk drives to form a single storage assembly, thereby providing a larger storage space. For example, JBOD can be applied to fields such as big data analysis, multimedia storage or data archiving.

The electronic device 10 is configured to be disposed in the chassis 40. The chassis 40 is made of, for example, iron. For example, the thermal conductivity of the iron is 63 W/(m·K), the specific heat of the iron is 420 J/(kg·K), and the density of the iron is 7860 kg/m³. The electronic device 10 includes a cooling assembly 20 and a plurality of hard disk drives 30. The cooling assembly 20 includes a vapor chamber 21 and a plurality of thermally conductive structures 22. The vapor chamber 21 is made of, for example, aluminum. For example, the thermal conductivity of the aluminum is 203 W/(m·K), the specific heat of the aluminum is 2710 J/(kg·K), and the density of the aluminum is 913 kg/m³. The vapor chamber 21 has a fluid inlet 211, a fluid outlet 212, an inflow and outflow portion 213, a heat exchanging portion 214 and a reflowing portion 215. The fluid inlet 211 is configured for a cooling fluid to flow into the vapor chamber 21. The fluid outlet 212 is configured for the cooling fluid to flow out of the vapor chamber 21.

The cooling fluid is, for example, water or refrigerant. In addition, for example, the temperature of the cooling fluid flowing into the vapor chamber 21 from the fluid inlet 211 is 40°C, and the flow rate of the cooling fluid flowing into the vapor chamber 21 from the fluid inlet 211 is 2 LPM (L/min). Furthermore, for example, the thermal conductivity of the cooling fluid is 0.6 W/(m·K), the specific heat of the cooling fluid is 4217 J/(kg·K), the density of the cooling fluid is 1000 kg/m³, and the dynamic viscosity of the cooling fluid is 0.001519 N·s/m².

The inflow and outflow portion 213 and the reflowing portion 215 are in fluid communication with two opposite ends of the heat exchanging portion 214, respectively. The fluid inlet 211 and the fluid outlet 212 are located on the inflow and outflow portion 213. In detail, the vapor chamber 21 has a partition 216. The partition 216 is disposed in the inflow and outflow portion 213 to divide an inner space of the inflow and outflow portion 213 into an inlet space S1 and an outlet space S2.

In addition, the vapor chamber 21 has an inlet opening 217 and two outlet openings 218. The fluid inlet 211 is in fluid communication with the inlet opening 217 via the inlet space S1, and the fluid outlet 212 is in fluid communication with the outlet opening 218 via the outlet space S2. The inlet space S1 is in fluid communication with the heat exchanging portion 214 via the inlet opening 217, and the outlet space S2 is in fluid communication with the heat exchanging portion 214 via the outlet opening 218. The inlet opening 217 is, for example, located between the outlet openings 218. The reflowing portion 215 is configured for the cooling fluid to reflow to the heat exchanging portion 214.

Each of the thermally conductive structures 22 includes a thermally conductive plate 221 and a plurality of heat pipes 222. The thermally conductive plate 221 are made of, for example, aluminum. The thermally conductive plates 221 are arranged side by side on two opposite sides of the vapor chamber 21. In detail, the thermally conductive plates 221 are thermally coupled to two opposite sides of the heat exchanging portion 214, respectively, and divide the two opposite sides of the heat exchanging portion 214 into a plurality of cooling spaces S. For example, an extending direction of the thermally conductive plates 221 is perpendicular to an extending direction of the vapor chamber 21, such that the thermally conductive plates 221 and the vapor chamber 21 together form in a shape of fishbone. The heat pipes 222 are connected to the two opposite sides of the vapor chamber 21, and are thermally coupled to the thermally conductive plates 221, respectively.

For example, the thermal conductivity of the heat pipes 222 is 30000 W/(m·K), the specific heat of the heat pipes 222 is 1000 J/(kg·K), and the density of the heat pipes 222 is 1000 kg/m³.

The hard disk drives 30 are located in the cooling spaces S, and are thermally coupled to the thermally conductive plates 221, respectively. The heat generated by the hard disk drives 30 during operation is transferred to the heat exchanging portion 214 of the vapor chamber 21 via the thermally conductive plates 221. In addition, the heat transferring efficiency between the thermally conductive plates 221 and the heat exchanging portion 214 is further improved via the heat pipes 222. The hard disk drives 30 located in each of the cooling spaces S are arranged, for example, along an extending direction of the thermally conductive plates 221. Furthermore, for example, the thermal conductivity of the hard disk drives 30 is 110 W/(m·K), the specific heat of the hard disk drives 30 is 1000 J/(kg·K), and the density of the hard disk drives 30 is 1000 kg/m³.

In this embodiment, the thermally conductive structures 22 are arranged side by side on the two opposite sides of the vapor chamber 21 to together form in the shape of fishbone and form the cooling spaces S for the hard disk drives 30 to be disposed therein. Therefore, the heat generated by the hard disk drives 30 during operation can be transferred to the vapor chamber 21 separately, thereby allowing the heat to be transferred to the vapor chamber 21 more evenly. For example, after the hard disk drives 30 are cooled by the cooling assembly 20, the maximum temperature of the hard disk drives 30 is less than or equal to 56.1°C. Accordingly, the cooling efficiency for the hard disk drives 30 can be improved.

In addition, an overall structure of the electronic device 10 can be simplified via the cooling assembly 20 in the shape of fishbone, thereby facilitating operations such as replacing the hard disk drives 30. Furthermore, the cooling mechanism is prevented from being failed by prevented the leakage of the cooling fluid via the structural design of the vapor chamber 21 and the thermally conductive structures 22 aforementioned.

In this embodiment, there are multiple thermally conductive structures 22 and multiple cooling spaces S, but the invention is not limited thereto. In other embodiments, there may be one thermally conductive structure and multiple cooling space merely.

In this embodiment, each of the thermally conductive structures 22 includes a thermally conductive plate 221 and multiple heat pipes 222, but the invention is not limited thereto. In other embodiments, the thermally conductive structures may be, for example, vapor chambers.

In this embodiment, there are multiple hard disk drives 30, but the invention is not limited thereto. In other embodiments, there may be one hard disk drive merely.

In this embodiment, there are one fluid inlet 211 and one fluid outlet 212 merely, but the invention is not limited thereto. In other embodiments, there may be multiple fluid inlets and multiple fluid outlets.

In this embodiment, there are one inlet opening 217 merely and two outlet openings 218, but the invention is not limited thereto. In other embodiments, there may be multiple inlet openings and one or more than two outlet opening(s).

In this embodiment, the inlet opening 217 is located between the outlet openings 218, but the invention is not limited thereto. In other embodiments, the inlet opening may be located on a side of the outlet openings.

In this embodiment, each of the thermally conductive structures 22 includes multiple heat pipes 222, but the invention is not limited thereto. In other embodiments, each of the thermally conductive structures may include one heat pipe merely, or the thermally conductive structures may not include heat pipes.

In this embodiment, the transmission of the heat generated by the hard disk drives 30 is shown in FIG. 4. Since the hard disk drives 30 are symmetrically arranged, and the hard disk drives 30 have the same structure, only one hard disk drive 30 will be described below. When the heat is generated by the hard disk drive 30 during operation, the heat is transferred to the two adjacent thermally conductive plates 221 and the heat pipes 222 along directions A and B parallel in which long sides of the hard disk drives 30 extend, and is transferred to the two adjacent thermally conductive plates 221 and the heat pipes 222 along directions C and D parallel in which short sides of the hard disk drives 30 extend. Then, the heat is then transferred from the two adjacent thermally conductive plates 221 and the heat pipes 222 to the heat exchanging portion 214 along a direction E to allow the cooling fluid to perform the heat exchange. Accordingly, the hard disk drives 30 can be cooled. The heat exchange process performed in the heat exchanging portion 214 will be further described below.

In this embodiment, during the heat exchange performed process in the heat exchanging portion 214, the flow of the cooling fluid is shown in FIG. 5. After the cooling fluid flows into the inlet space S1 in the inflow and outflow portion 213 from the fluid inlet 211 along a direction F, the cooling fluid flows into the heat exchanging portion 214 from the inlet opening 217 along a direction G. Then, the cooling fluid flows in the heat exchanging portion 214 toward the reflowing portion 215 along a direction H. Then, after the cooling fluid flows to the reflowing portion 215, the cooling fluid turns along directions I and J to reflow to the heat exchanging portion 214, and flows in the heat exchanging portion 214 toward the inflow and outflow portion 213 along a direction K. When the cooling fluid flows in the heat exchanging portion 214, the cooling fluid absorbs the heat transferred from the hard disk drives 30 to the heat exchanging portion 214 to cool the hard disk drives 30.

Then, the cooling fluid flows into the outlet space S2 in the inflow and outflow portion 213 from the outlet openings 218 along directions L and M. Then, the cooling fluid out of the outlet space S2 from the fluid outlet 212 along a direction N to perform the next cooling process. Accordingly, the hard disk drives 30 can be cooled by the circulation of the cooling fluid.

According to the electronic device and the cooling assembly disclosed in the above embodiment, the thermally conductive structures are arranged side by side on the two opposite sides of the vapor chamber to together form in the shape of fishbone and form the cooling spaces for the hard disk drives to be disposed. Therefore, the heat generated by the hard disk drives during operation can be transferred to the vapor chamber separately, thereby the heat transmission can be more evenly. For example, after the hard disk drives are cooled by the cooling assembly, the maximum temperature of the hard disk drives is less than or equal to 56.1°C. Accordingly, the cooling efficiency for the hard disk drives can be improved.

In addition, an overall structure of the electronic device can be simplified via the cooling assembly in the shape of fishbone, thereby facilitating operations such as replacing the hard disk drives. Furthermore, the risk of failure of cooling caused by leakage of the cooling fluid can be reduced via the structural design of the vapor chamber and the thermally conductive structures aforementioned.

It will be apparent to those skilled in the art that various modifications and variations can be made to the invention. It is intended that the specification and examples be considered as exemplary embodiments only, with the scope of the invention being indicated by the following claims.

What is claimed is:

1. An electronic device, comprising:
a cooling assembly, comprising:
a vapor chamber; and
a plurality of thermally conductive structures, arranged side by side on two opposite sides of the vapor chamber to form at least one cooling space, and the plurality of thermally conductive structures are thermally coupled to the vapor chamber; and
at least one hard disk drive, located in the at least one cooling space and thermally coupled to one of the plurality of thermally conductive structures.

2. The electronic device according to claim 1, wherein each of the plurality of thermally conductive structures comprises a thermally conductive plate, the at least one cooling space comprises a plurality of cooling spaces, the plurality of thermally conductive plates are arranged side by side on the two opposite sides of the vapor chamber, the plurality of thermally conductive plates divide the two opposite sides of the vapor chamber into the plurality of cooling spaces, the plurality of thermally conductive plates are thermally coupled to the vapor chamber, and the at least one hard disk drive is thermally coupled to one of the plurality of thermally conductive plates.

3. The electronic device according to claim 2, wherein an extending direction of the plurality of thermally conductive plates is perpendicular to an extending direction of the vapor chamber.

4. The electronic device according to claim 2, wherein the at least one hard disk drive comprises a plurality of hard disk drives, the plurality of hard disk drives are located in the plurality of cooling spaces, respectively, and the plurality of hard disk drives located in each of the plurality of cooling spaces are arranged along an extending direction of the plurality of thermally conductive plates.

5. The electronic device according to claim 2, wherein each of the plurality of thermally conductive structures further comprises at least one heat pipe, the plurality of heat pipes are connected to the two opposite sides of the vapor chamber, and are thermally coupled to the plurality of thermally conductive plates, respectively.

6. The electronic device according to claim 1, wherein the vapor chamber has at least one fluid inlet and at least one fluid outlet, the at least one fluid inlet is configured for a cooling fluid to flow into the vapor chamber, and the at least one fluid outlet is configured for the cooling fluid to flow out of the vapor chamber.

7. The electronic device according to claim 6, wherein the vapor chamber further has an inflow and outflow portion, a heat exchanging portion and a reflowing portion, the inflow and outflow portion and the reflowing portion are in fluid communication with two opposite ends of the heat exchanging portion, respectively, the at least one fluid inlet and the at least one fluid outlet are located on the inflow and outflow portion, the plurality of thermally conductive structures are thermally coupled to two opposite sides of the heat exchanging portion, respectively, and the reflowing portion is configured for the cooling fluid to reflow to the heat exchanging portion.

8. A cooling assembly, configured for at least one hard disk drive to be disposed, comprising:
a vapor chamber; and
a plurality of thermally conductive structures, arranged side by side on two opposite sides of the vapor chamber to form at least one cooling space, the plurality of thermally conductive structures are thermally coupled to the vapor chamber, and the at least one cooling space is configured for the at least one hard disk drive to be thermally coupled to one of the plurality of thermally conductive structures.

9. The cooling assembly according to claim 8, wherein each of the plurality of thermally conductive structures comprises a thermally conductive plate and at least one heat pipe, the at least one cooling space comprises a plurality of cooling spaces, the plurality of thermally conductive plates are arranged side by side on the two opposite sides of the vapor chamber, the plurality of thermally conductive plates divide the two opposite sides of the vapor chamber into the plurality of cooling spaces, one of the plurality of thermally conductive plates is configured for the at least one hard disk drive to be thermally coupled, the plurality of heat pipes are connected to the two opposite sides of the vapor chamber, and are thermally coupled to the plurality of thermally conductive plates, respectively.

10. The cooling assembly according to claim 9, wherein an extending direction of the plurality of thermally conductive plates is perpendicular to an extending direction of the vapor chamber.
